(19) United States
(12) Patent Application Publication
(10) Pub. No.: US 2026/0349268 A1
(43) Pub. Date: Nov. 5, 2026

(54) LIGHT EMITTING CHIP AND OPTICAL MODULE

(71) Applicant: InnoLight Technology (Suzhou) Ltd., Suzhou (CN)

(72) Inventors: DE-FEN GUO, Suzhou (CN); XIAN-YAO LI, Suzhou (CN)

(21) Appl. No.: 19/706,911

(22) Filed: Jun. 12, 2026

Related U.S. Application Data
(63) Continuation of application No. PCT/CN2024/129593, filed on Nov. 4, 2024.

(30) Foreign Application Priority Data
Dec. 13, 2023 (CN) 202311707502.3

(51) Int. Cl. G02B 27/28; H10H 20/855

(52) U.S. Cl. CPC G02B 27/283; H10H 20/855

(57) ABSTRACT

A light emitting chip and an optical module. The light emitting chip comprises, in the transmission direction of optical signals, light modulation units and first coupling units, which are connected to each other, the light modulation units being configured for modulating received light and then outputting same, and the first coupling units being provided at the output end of the light emitting chip and being configured for receiving signal light output by the light modulation units after modulation, and coupling the signal light output after modulation and outputting same, and further comprises control units, wherein, when there is light that is reversely transmitted from the first coupling units to the light modulation units, the control units are configured for at least preventing vertically polarized light from being transmitted to the light modulation units.

### CROSS-REFERENCE TO RELATED PATENT APPLICATION

This application is a continuation application of International Patent Application Ser. No. PCT/CN2024/129593, filed on Nov. 4, 2024, which the international application was published on Jun. 19, 2025, as International Publication No. WO 2025/123999A1, and claims the priority of China Patent Application No. CN202311707502.3, filed on Dec. 13, 2023, in People's Republic of China. The entirety of each of the above patent applications is hereby incorporated by reference herein and made a part of this specification.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present invention relates to the field of semiconductor integration technology, and in particular to a light emitting chip and an optical module.

BACKGROUND OF THE DISCLOSURE

In general, the working process of the light emitting chip can be briefly described as follows: the light source is coupled into the light emitting chip through the input end mode spot conversion structure, and then is transmitted to the basic units or integrated devices on the optical chip such as the beam splitter and the modulator in sequence through the waveguide, and is finally output by the output end mode spot conversion structure.

The standard requirement for the light reflectance at the output end of the light emitting chip is less than −26 dB. That is to say, when light is reversely coupled from the output end of the light emitting chip into the light emitting chip, that is, when light is input from the output end of the light emitting chip to the input end of the light emitting chip, the wavelength of the light satisfies the range of ±6.5 nm of the central wavelength and is in any polarization state, and the light reflectance at the output end of the light emitting chip is required to be less than −26 dB.

Since the light source coupled to the input end of the light emitting chip is generally horizontally polarized light, the integrated devices on the light emitting chip all operate in a horizontal polarization state. Therefore, for the light reversely input from the output end of the light emitting chip, if it is horizontally polarized light, the reflection is small; if it is vertically polarized light, some basic units or integrated devices on the light emitting chip will have a larger reflection.

### SUMMARY OF THE DISCLOSURE

The object of the present invention is to provide a light emitting chip and an optical module to reduce light reflection at the output end of the light emitting chip.

To achieve one of the above-mentioned objects of the invention, an embodiment of the present invention provides a light emitting chip, wherein, the light emitting chip comprises, in a transmission direction of optical signals, a light modulation unit and a first coupling unit, that are connected to each other, wherein the light modulation unit is configured for modulating a received light and then outputting same, and the first coupling unit is provided at an output end of the light emitting chip and is configured for receiving a signal light output by the light modulation unit after modulation, and for coupling the signal light output after modulation and outputting same;
and further comprises a control unit, wherein, when there is light that is reversely transmitted from the first coupling unit to the light modulation unit, the control unit is configured for at least preventing a vertically polarized light from being transmitted to the light modulation unit.

As a further improvement of an embodiment of the present invention, the control unit is arranged between the light modulation unit and the first coupling unit, and the control unit allows a horizontally polarized light to be transmitted to the light modulation unit.

As a further improvement of an embodiment of the present invention, the control unit is a polarizer.

As a further improvement of an embodiment of the present invention, the control unit comprises a polarization separation module and an absorption module, the polarization separation module is connected to an output end of the light modulation unit and an input end of the first coupling unit, and the absorption module is connected to a reverse output end of the polarization separation module; and
the polarization separation module outputs the horizontally polarized light reversely transmitted from the first coupling unit to the light modulation unit, and outputs a light of other polarization states reversely transmitted from the first coupling unit to the absorption module, and the absorption module absorbs the received light.

As a further improvement of an embodiment of the present invention, the control unit comprises a polarization separation module and a dissipation module, the polarization separation module is connected to the output end of the light modulation unit and the input end of the first coupling unit, and the dissipation module is connected to the reverse output end of the polarization separation module; and
the polarization separation module outputs the horizontally polarized light reversely transmitted from the first coupling unit to the light modulation unit, and outputs a light of other polarization states reversely transmitted from the first coupling unit to the dissipation module, and the dissipation module dissipates an optical power of the received light to 0.

As a further improvement of an embodiment of the present invention, the polarization separation module is a polarization separation device or a polarization rotation separation device;
when the polarization separation module is a polarization separation device, the polarization separation module directly outputs the vertically polarized light reversely transmitted from the first coupling unit; and
when the polarization separation module is a polarization rotation separation device, the polarization separation module outputs the vertically polarized light reversely transmitted from the first coupling unit after polarization rotation.

As a further improvement of an embodiment of the present invention, the absorption module is a germanium material absorption structure.

As a further improvement of an embodiment of the present invention, the dissipation module is a loss waveguide or a PN junction absorption structure.

As a further improvement of an embodiment of the present invention, the light emitting chip further comprises a second coupling unit, and the second coupling unit is connected to the light modulation unit and is configured to couple an external input light and transmit the external input light to the light modulation unit.

As a further improvement of an embodiment of the present invention, the first coupling unit and the second coupling unit are both edge couplers.

As a further improvement of an embodiment of the present invention, the light modulation unit at least comprises a light modulator and an optical power monitoring unit, the light modulator is connected to the second coupling unit and the control unit, and the optical power monitoring unit is connected to an output end of the light modulator for monitoring an optical power at the output end of the light modulator.

As a further improvement of an embodiment of the present invention, the light emitting chip further comprises a splitting unit, the splitting unit is connected to the output end of the second coupling unit and is configured to split a coupled light after a spot is reduced into at least two transmission paths, and each of the at least two transmission paths is connected to the light modulation unit, the control unit and the first coupling unit.

To achieve the above-mentioned object of the invention, the present invention provides an optical module, and the optical module comprises the above-mentioned light emitting chip.

The beneficial effect of the present invention is that a control unit is set between the input end and the output end of the light emitting chip. For light of any polarization state input in reverse from the output end of the light emitting chip, after passing through the control unit, at least the vertically polarized light can be prevented from being transmitted to the light modulation unit, thereby avoiding the vertically polarized light from being transmitted in the light emitting chip and causing a large light reflection at the output end of the light emitting chip.

### BRIEF DESCRIPTION OF THE DRAWINGS

FIG. 1 is a schematic structural diagram of a light emitting chip in one embodiment of the present invention;

FIG. 2 is a schematic diagram of a test optical path structure of light reflection at an output end of the light emitting chip in one embodiment of the present invention;

FIG. 3 is a schematic diagram of a working process of a control unit in one embodiment of the present invention;

FIG. 4 is a schematic structural diagram of the light emitting chip in another embodiment of the present invention;

FIG. 5 is a schematic diagram of the working process of the control unit in another embodiment of the present invention (when a polarization separation module is a polarization separator); and

FIG. 6 is a schematic diagram of the working process of the control unit in another embodiment of the present invention (when the polarization separation module is a polarization rotation separator).

### DETAILED DESCRIPTION OF THE EXEMPLARY EMBODIMENTS

In order to make the purpose, technical solutions, and advantages of this application clearer, the technical solutions of this application will be clearly and completely described below in conjunction with the specific implementation methods of this application and the corresponding drawings. Obviously, the described implementation methods are only part of the implementation methods of this application, not all of the implementation methods. Based on the implementation methods in this application, all other implementation methods obtained by ordinary technicians in this field without making creative work are within the scope of protection of this application.

The embodiments of the present invention are described in detail below, and examples of the embodiments are shown in the accompanying drawings, wherein the same or similar reference numerals throughout represent the same or similar elements or elements having the same or similar functions. The embodiments described below with reference to the accompanying drawings are exemplary and are only used to explain the present invention, and cannot be understood as limiting the present invention.

The present invention provides a light emitting chip, which comprises a light modulation unit and a first coupling unit that are interconnected along a transmission direction of optical signals. The light modulation unit is configured to modulate a received light and then output the received light. The first coupling unit is arranged at the output end of the light emitting chip, and is configured to receive the signal light output by the light modulation unit after modulation, and couple a modulated signal light and then output the modulated signal light. The light emitting chip further comprises a control unit, which is configured to at least prevent the vertically polarized light from being transmitted to the light modulation unit when light is transmitted reversely from the first coupling unit.

The light emitting chip in the present invention may be a modulator chip integrated with a light source, a modulator chip receiving external input light, or a light emitting chip integrated with a light receiving chip.

This embodiment will be specifically described by taking a modulator chip that receives external input light as an example, and the light emitting chip further comprises a second coupling unit, and the second coupling unit is connected to the light modulation unit and is configured to couple an external input light and transmit the external input light to the light modulation unit.

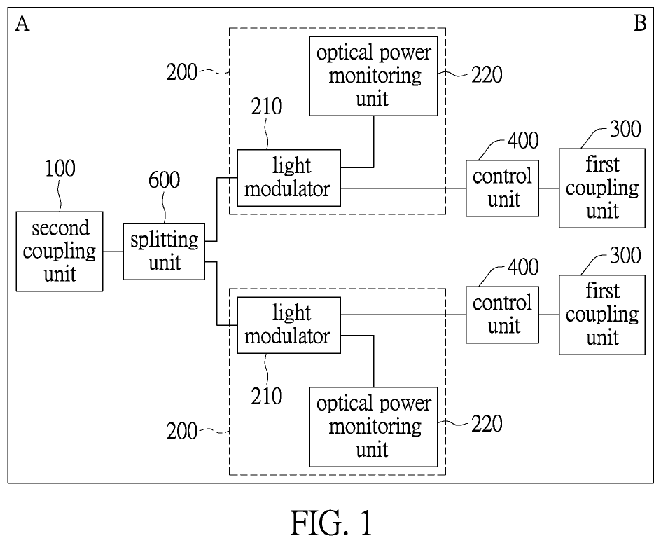

As shown in FIG. 1, a light emitting chip provided in this embodiment comprises a second coupling unit 100, a light modulation unit 200, and a first coupling unit 300 connected in sequence from an input terminal A of the light emitting chip to an output terminal B of the light emitting chip.

The second coupling unit 100 is disposed at the input terminal A of the light emitting chip, and is configured to couple the external input light and transmit the external input light to the light modulation unit 200.

In one embodiment of the present invention, the second coupling unit 100 is an edge coupler, such as a spot converter. Specifically, when the second coupling unit 100 is a spot converter, and when an external light source is arranged at the input end A of the light emitting chip and optically coupled with the second coupling unit 100, the second coupling unit 100 receives the input light of the external light source and reduces the spot of the input light, so that the coupled light after the spot reduction can be transmitted between the silicon waveguide on the light emitting chip and other optical units or optical devices.

In other embodiments of the present invention, the second coupling unit 100 may also be a vertical coupler, such as a grating coupler.

The present invention does not limit the specific type of coupling devices of the second coupling unit 100, and the design can be adjusted according to actual needs.

The input end of the light modulation unit 200 is connected to the output end of the second coupling unit 100. The light modulation unit 200 receives the coupled light with reduced light spot, modulates the coupled light with reduced light spot, and then outputs the coupled light.

Specifically, the light modulation unit 200 at least comprises a light modulator 210 and an optical power monitoring unit 220. The light modulator 210 is connected to the second coupling unit 100 and the first coupling unit 300. The optical power monitoring unit 220 is connected to the output end of the light modulator 210, and is configured to monitor the optical power at the output end of the light modulator 210.

Naturally, the light modulation unit 200 may also include functional devices, such as a wavelength division multiplexer connected to the light modulator 210. The present invention does not limit the type, quantity and location of the functional device, and the design can be adjusted according to the actual design requirements and application scenarios of the light emitting chip.

The first coupling unit 300 is disposed at the output end of the light emitting chip, and is connected to the output end of the light modulation unit 200. It is configured to receive the signal light output after modulation by the light modulation unit 200, and couple the modulated signal light and then output the modulated signal light.

Specifically, the first coupling unit 300 is an edge coupler, such as a spot converter. When the first coupling unit 300 is a spot converter, it is configured to receive the signal light output after modulation by the light modulation unit 200, amplify the spot of the modulated signal light, and then couple and output the modulated signal light with the optical fiber at the output end of the light emitting chip.

Generally, the light reflection standard requirement at the output terminal B of the light emitting chip is less than −26 dB. Since the light source coupled to the input terminal A of the light emitting chip is horizontally polarized light, and the second coupling unit 100, the light modulation unit 200, the first coupling unit 300, and the optical units such as the silicon waveguide for light transmission are designed to work in the horizontal polarization state, when light of any polarization state is input from the output terminal B of the light emitting chip into the light emitting chip, the second coupling unit 100, the light modulation unit 200, the first coupling unit 300, and the optical units such as the silicon waveguide for light transmission have a large light reflection for light of other polarization states (such as vertically polarized light).

Furthermore, the light emitting chip in this embodiment further comprises a control unit 400, which is arranged between the light modulation unit 200 and the first coupling unit 300. When light is transmitted reversely from the first coupling unit 300 to the second coupling unit 100, the control unit 400 only allows the horizontally polarized light to pass, or prevents the vertically polarized light from passing through.

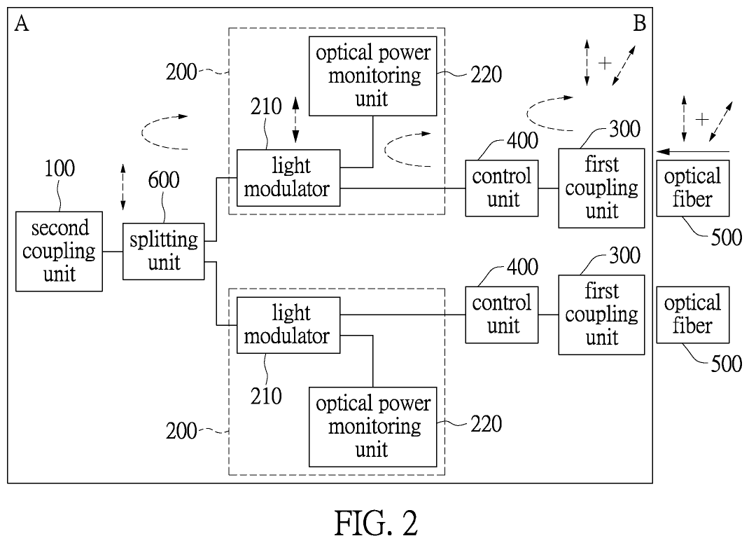

In conjunction with FIG. 2, when light with an arbitrary polarization state is coupled to the first coupling unit 300 through the optical fiber 500, the light with an arbitrary polarization state is transmitted from the first coupling unit 300 in the reverse direction to the light emitting chip. After the light passes through the control unit 400, the control unit 400 transmits only the horizontally polarized light in the direction toward the light modulation unit 200. The setting of the control unit 400 can prevent the vertically polarized light input from the output end of the light emitting chip from being transmitted in the light emitting chip and causing a large light reflection. That is, when the wavelength of the light input at the output end of the light emitting chip is within the range of ±6.5 nm of the central wavelength and is an arbitrarily polarized light, the light reflection at the output end of the light emitting chip can meet the requirement of being less than −26 dB.

In one embodiment of the present invention, the control unit 400 is a polarizer.

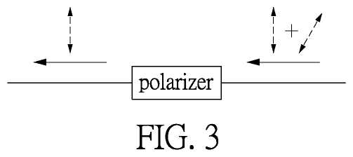

As shown in FIG. 3, when the control unit 400 is a polarizer, the polarization state of the output light of the polarizer can be controlled to be a horizontal polarization state by adjusting the waveguide structure design in the polarizer.

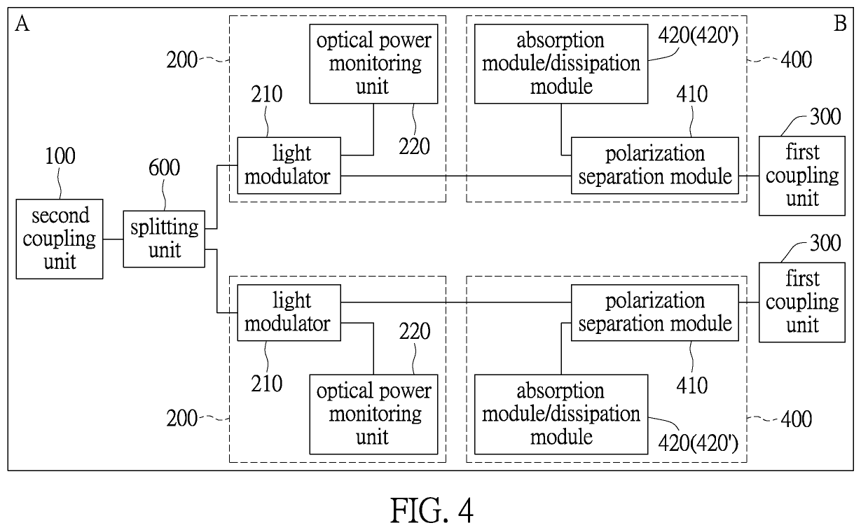

In another embodiment of the present invention, as shown in FIG. 4, the control unit 400 comprises a polarization separation module 410 and an absorption module 420. The polarization separation module 410 is connected to the output end of the light modulation unit 200 and the input end of the first coupling unit 300. The absorption module 420 is connected to the reverse output end of the polarization separation module 410.

The polarization separation module 410 outputs the horizontally polarized light transmitted reversely from the first coupling unit 300 to the light modulation unit 200, and outputs the light of other polarization states transmitted reversely from the first coupling unit 300 to the absorption module 420. The absorption module 420 absorbs the received light.

Specifically, the polarization separation module 410 is a polarization separation device (PBS) or a polarization rotation separation device (PSR).

When the polarization separation module 410 is a polarization separation device, the polarization separation module 410 directly outputs the vertically polarized light transmitted reversely from the first coupling unit 300. When the polarization separation module 410 is a polarization rotation separation device, the polarization separation module 410 outputs the vertically polarized light transmitted reversely from the first coupling unit 300 after polarization rotation.

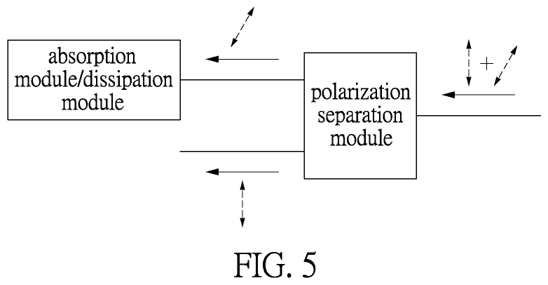

In conjunction with FIG. 5, when the polarization separation module 410 is a polarization separation device, and when light with any polarization state is coupled to the first coupling unit 300 through the optical fiber 500, and the light with any polarization state is reversely transmitted from the first coupling unit 300 to the light emitting chip, the polarization separation module 410 outputs the horizontally polarized light reversely transmitted from the first coupling unit 300 to the light modulation unit 200, and directly outputs the vertically polarized light reversely transmitted from the first coupling unit 300 to the absorption module 420. The absorption module 420 absorbs the received vertically polarized light, so as to prevent the vertically polarized light from being transmitted in the light emitting chip and causing a large light reflection at the output end B of the light emitting chip.

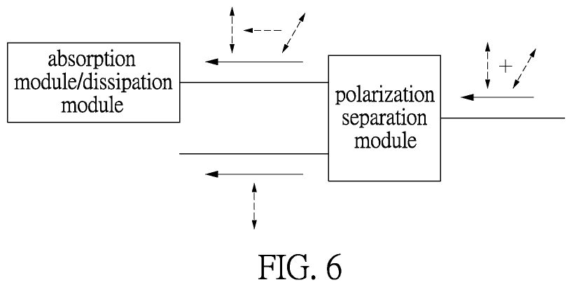

In conjunction with FIG. 6, when the polarization separation module 410 is a polarization rotation separation device, and when light with an arbitrary polarization state is coupled to the first coupling unit 300 through the optical fiber 500, and the light with an arbitrary polarization state is transmitted reversely from the first coupling unit 300 to the light emitting chip, the polarization separation module 410 outputs the horizontally polarized light transmitted reversely from the first coupling unit 300 to the light modulation unit 200, performs polarization rotation on the vertically polarized light transmitted reversely from the first coupling unit 300, and outputs the horizontally polarized light to the absorption module 420 after polarization rotation. The absorption module 420 absorbs the received horizontally polarized light, so as to prevent the vertically polarized light from being transmitted in the light emitting chip and causing a large light reflection at the output end B of the light emitting chip.

Specifically, the absorption module 420 is a germanium material absorption structure.

In another embodiment of the present invention, the control unit 400 comprises a polarization separation module 410 and a dissipation module 420′. The polarization separation module 410 is connected to the output end of the light modulation unit 200 and the input end of the first coupling unit 300. The dissipation module 420′ is connected to the reverse output end of the polarization separation module 410.

The polarization separation module 410 outputs the horizontally polarized light transmitted reversely from the first coupling unit 300 to the light modulation unit 200, and outputs the light of other polarization states transmitted reversely from the first coupling unit 300 to the dissipation module 420′. The dissipation module 420′ dissipates the optical power of the received light to 0.

Specifically, the polarization separation module 410 is a polarization separation device (PBS) or a polarization rotation separation device (PSR).

When the polarization separation module 410 is a polarization separation device, the polarization separation module 410 directly outputs the vertically polarized light transmitted reversely from the first coupling unit 300. When the polarization separation module 410 is a polarization rotation separation device, the polarization separation module 410 outputs the vertically polarized light transmitted reversely from the first coupling unit 300 after polarization rotation.

Similarly, in conjunction with FIG. 5, when the polarization separation module 410 is a polarization separation device, and when light with an arbitrary polarization state is coupled to the first coupling unit 300 through the optical fiber 500, and the light with an arbitrary polarization state is reversely transmitted from the first coupling unit 300 to the light emitting chip, the polarization separation module 410 outputs the horizontally polarized light reversely transmitted from the first coupling unit 300 to the light modulation unit 200, and directly outputs the vertically polarized light reversely transmitted from the first coupling unit 300 to the dissipation module 420′. The dissipation module 420′ dissipates the optical power of the received vertically polarized light to 0, thereby avoiding the vertically polarized light from being transmitted in the light emitting chip and causing a large light reflection at the output end B of the light emitting chip.

In conjunction with FIG. 6, when the polarization separation module 410 is a polarization rotation separation device, and when light with an arbitrary polarization state is coupled to the first coupling unit 300 through the optical fiber 500, and the light with an arbitrary polarization state is reversely transmitted from the first coupling unit 300 to the light emitting chip, the polarization separation module 410 outputs the horizontally polarized light reversely transmitted from the first coupling unit 300 to the light modulation unit 200, performs polarization rotation on the vertically polarized light reversely transmitted from the first coupling unit 300, and outputs the horizontally polarized light to the dissipation module 420′ after the polarization rotation. The dissipation module 420′ dissipates the optical power of the received horizontally polarized light to 0, thereby avoiding the vertically polarized light from being transmitted in the light emitting chip and causing a large light reflection at the output end B of the light emitting chip.

Specifically, the dissipation module 420′ is a low-reflection loss waveguide or PN junction absorption structure.

Furthermore, the light emitting chip in this embodiment further comprises a splitting unit 600. The splitting unit 600 is connected to the output end of the second coupling unit 100 and is configured to split the coupled light output by the second coupling unit 100 into at least two transmission paths, each of which is connected to the light modulation unit 200, the control unit 400 and the first coupling unit 300.

Specifically, the splitting unit 600 is a 3 dB coupler, which splits the coupled light output by the second coupling unit 100 into two transmission paths, and each transmission path is connected to the light modulation unit 200, the control unit 400, and the first coupling unit 300.

Naturally, the splitting unit 600 can also be designed as a multi-channel splitting structure, and it is only necessary to ensure that the optical power of each transmission path meets the transmission requirements of subsequent silicon-based optical devices.

Furthermore, another optical power monitoring unit is provided on each transmission path after the output of the splitting unit 600. Said optical power monitoring unit is connected to the output end of the splitting unit 600, and is configured to monitor the output optical power on each transmission path of the splitting unit 600.

The present invention further provides an optical module, and the optical module comprises the light emitting chip as described in any one of the above embodiments.

In summary, the present invention sets a control unit before the mode spot conversion unit at the output end of the light emitting chip. For light of any polarization state reversely input from the output end of the light emitting chip, after passing through the control unit, it can at least prevent the vertically polarized light from being transmitted to the light modulation unit, thereby avoiding the vertically polarized light from being transmitted in the light emitting chip and causing a large light reflection at the output end of the light emitting chip. That is, when the wavelength of light input at the output end of the light emitting chip is within the range of ±6.5 nm of the central wavelength and is any polarized light, the light reflection at the output end of the light emitting chip can meet the requirement of being less than −26 dB.

It should be understood that, although this specification is described according to implementation modes, not every implementation mode contains only one independent technical solution. This description of the specification is only for the sake of clarity. Those skilled in the art should consider the specification as a whole. The technical solutions in each implementation mode may also be appropriately combined to form other implementation modes that can be understood by those skilled in the art.

The series of detailed descriptions listed above are only specific descriptions of feasible implementation methods of the present invention. They are not intended to limit the scope of protection of the present invention. Any equivalent implementation methods or changes that do not deviate from the technical spirit of the present invention should be included in the scope of protection of the present invention.

1. A light emitting chip, wherein, the light emitting chip comprises, in a transmission direction of optical signals, a light modulation unit and a first coupling unit that are connected to each other, wherein the light modulation unit is configured for modulating a received light and then outputting same, and the first coupling unit is provided at an output end of the light emitting chip and is configured for receiving a signal light output by the light modulation unit after modulation, and for coupling the signal light output after modulation and outputting same;
and further comprises a control unit, wherein, when there is light that is reversely transmitted from the first coupling unit to the light modulation unit, the control unit is configured for at least preventing a vertically polarized light from being transmitted to the light modulation unit.

2. The light emitting chip according to claim 1, wherein, the control unit is arranged between the light modulation unit and the first coupling unit, and the control unit allows a horizontally polarized light to be transmitted to the light modulation unit.

3. The light emitting chip according to claim 2, wherein, the control unit is a polarizer.

4. The light emitting chip according to claim 2, wherein, the control unit comprises a polarization separation module and an absorption module, the polarization separation module is connected to an output end of the light modulation unit and an input end of the first coupling unit, and the absorption module is connected to a reverse output end of the polarization separation module; and
the polarization separation module outputs the horizontally polarized light reversely transmitted from the first coupling unit to the light modulation unit, and outputs a light of other polarization states reversely transmitted from the first coupling unit to the absorption module, and the absorption module absorbs the received light.

5. The light emitting chip according to claim 2, wherein, the control unit comprises a polarization separation module and a dissipation module, the polarization separation module is connected to the output end of the light modulation unit and the input end of the first coupling unit, and the dissipation module is connected to the reverse output end of the polarization separation module; and
the polarization separation module outputs the horizontally polarized light reversely transmitted from the first coupling unit to the light modulation unit, and outputs a light of other polarization states reversely transmitted from the first coupling unit to the dissipation module, and the dissipation module dissipates an optical power of the received light to 0.

6. The light emitting chip according to claim 4, wherein, the polarization separation module is a polarization separation device or a polarization rotation separation device;
when the polarization separation module is a polarization separation device, the polarization separation module directly outputs the vertically polarized light reversely transmitted from the first coupling unit; and
when the polarization separation module is a polarization rotation separation device, the polarization separation module outputs the vertically polarized light reversely transmitted from the first coupling unit after polarization rotation.

7. The light emitting chip according to claim 4, wherein, the absorption module is a germanium material absorption structure.

8. The light emitting chip according to claim 5, wherein, the dissipation module is a loss waveguide or a PN junction absorption structure.

9. The light emitting chip according to claim 1, wherein, the light emitting chip further comprises a second coupling unit, and the second coupling unit is connected to the light modulation unit and is configured to couple an external input light and transmit the external input light to the light modulation unit.

10. The light emitting chip according to claim 9, wherein, the first coupling unit and the second coupling unit are both edge couplers.

11. The optical transmitting chip according to claim 9, wherein, the light modulation unit at least comprises a light modulator and an optical power monitoring unit, the light modulator is connected to the second coupling unit and the control unit, and the optical power monitoring unit is connected to an output end of the light modulator for monitoring an optical power at the output end of the light modulator.

12. The light emitting chip according to claim 9, wherein, the light emitting chip further comprises a splitting unit, the splitting unit is connected to the output end of the second coupling unit and is configured to split a coupled light after a spot is reduced into at least two transmission paths, and each of the at least two transmission paths is connected to the light modulation unit, the control unit, and the first coupling unit.

13. An optical module, wherein, the optical module comprises the light emitting chip according to claim 1.
